(19) United States
(12) Patent Application Publication
(10) Pub. No.: US 2010/0045287 A1
(43) Pub. Date: Feb. 25, 2010

(54) SENSOR

(75) Inventor: Hans Van Zon, Waalre (NL)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP, B.V., Eindhoven (NL)

(21) Appl. No.: 12/520,265

(22) PCT Filed: Dec. 11, 2007
(86) PCT No.: PCT/IB2007/055030

§ 371 Date: Jun. 19, 2009

(30) Foreign Application Priority Data
Dec. 27, 2006 (EP) 06026902.4
Dec. 11, 2007 (IB) PCT/IB2007/055030

(51) Int. Cl. G01R 33/00

(52) U.S. Cl. 324/262

(57) ABSTRACT

The invention relates to a sensor arrangement (1) comprising a magnet (2), a magnetic field sensor (3) and a twistable or rotatable rod (4), characterized in that the magnet (2) is arranged below the magnetic field sensor (3) and the twistable or rotatable rod (4) is arranged above the magnetic field sensor (3), wherein the rod (4) comprises a lower surface (6) generating a tilt angle between the surface and the plane of the magnetic field sensor.

### FIELD OF THE INVENTION

The invention relates to a sensor arrangement especially with a magneto resistive sensor, more specifically with a sensor based on an Anisotropic Magneto-Resistance (AMR).

### BACKGROUND OF THE INVENTION

An angular sensor based on the AMR technology consists according to prior art of a package containing the magnetic sensor element made of a NiFe alloy which is capable of measuring the direction of an external magnetic field and an external permanent magnet configuration which generates the external magnetic field. The permanent magnet is attached to the mechanism of which the angle has to be measured. Changing the orientation of the mechanism changes the direction of the permanent magnet and thus the direction of the magnetic field which is measured by the sensor. The permanent magnet has to generate a sufficiently strong magnetic field such that the magnetisation direction within the sensor material is sufficiently parallel to the external field.

For an AMR element the resistance can be described as R=R₀+ΔR₀*cos²α in which R₀ is the base resistance of the element, ΔR₀ the maximum resistance change due to the AMR effect and α the angle between the direction of the magnetisation and the direction of the current which runs through the element. The term cos²α is used to determine the field angle in an angle sensor. Since this term can be rewritten as (cos²α+1)/2, it is clear that the output of the sensor depends on the double field angle. The term becomes repetitive for field angles larger than 180 degrees. Therefore, the field angle range of an AMR angle sensor which makes use of this mechanism is restricted to 180 degrees.

DE 4317512 A1 discloses an AMR sensor and in this case not the cos²α term is used to provide the information about the angle, but the sensor is in its linear working region where the output is modulated by the direction of the applied field. It is essential that the sensor works in its linear region and therefore the applied external field of which the angle has to be measured can only be weak, such as is the case for the earth magnetic field. It is essential in such a device that the sensor does not work in a saturated mode. A disadvantage of such a sensor is, as is known for magnetic compasses, its sensitivity to external stray fields which disturb the angle measurement. Another disadvantage of a non-saturated sensor is its decreased signal-to-noise ratio.

WO 2006/035350 A1 and WO 2006/035371 A1 disclose a sensor configuration based on a saturated AMR sensor which is extremely sensitive to the tilt angle of a magnetically conductive piece of material such as e.g. a joystick for which the sensor originally has been designed. The sensor is sensitive to the tilt angle in two directions, X and Y. The principle of the sensor is the bending of magnetic field lines of a permanent magnet which is statically positioned underneath the sensor. The permanent magnetic field or more precisely the component of the permanent magnetic field in the plane of the sensor is strong enough to completely saturate the sensor. The bending is accomplished by changing the position of the magnetically conductive piece of material relative to the position of this magnet. The effect of the bending is a local change in the direction of the field while the strength of the magnetic field is maintained.

U.S. Pat. No. 6,326,781 B1 discloses a magneto resistive sensor where a permanent magnet is attached to a rotating part and the rotating permanent magnet is located above the sensor element. The stray field of this magnet has to be non-saturating which makes the sensor noisy and sensitive to external fields. The stray field has to be of uniform intensity and therefore the magnets must be relatively large with respect to the sensor. This is very expensive. Moreover, the sensor and magnets are individual parts which need to be combined. Therefore, this is not a single-sensor solution. The complete sensor part consists of 2 individually aligned sensors under 90 degrees, thus a multi-die solution. Therefore the costs will increase accordingly.

US 2004/0160220 A1 discloses an arrangement for measuring the angular position of an object by way of a turning permanent magnet and a sensor. In this prior art document the permanent magnet is attached to the rotating part too. The permanent magnet configuration has to be attached non-centrically to the rotating part which might cause unbalance to the rotating part. The permanent magnet configuration has to be large with respect to the sensors. This is expensive too. Moreover, the sensor and magnets are individual parts which need to be combined. Therefore, this is not a single-sensor solution. The complete sensor part consists of two individually aligned sensors which have to be mounted perpendicularly to a substrate, thus a multi-die solution and this is again expensive.

### SUMMARY OF THE INVENTION

It is an object of the invention to create a sensor arrangement to measure angles between 0 and 360° which uses the AMR magnetic field sensor, eg. as described in WO 2006/035350 A1 and WO 2006/035371 A1, and which is inexpensive in production.

The sensor arrangement according to the invention comprises a magnet, a magnetic field sensor and a twistable or rotatable rod wherein the magnet is arranged on one side of the magnetic field sensor and the twistable or rotatable rod is arranged on the other side of the magnetic field sensor, wherein the rod comprises a lower surface generating a tilt angle between the surface and the plane of the magnetic field sensor.

Therefore it is advantageous that the sensor arrangement comprises a housing, wherein the lower surface of the rod is arranged within the housing.

According to one embodiment of the invention, it is advantageous that the housing comprises a recess and at least one part of the rod is arranged in the recess of the housing. Accordingly it is advantageous that the recess is used to center the rod or the recess is used as or to carry a bearing between housing and the rod.

According to an other embodiment of the invention, it is advantageous that the sensor arrangement comprises a housing, wherein the lower surface of the rod is arranged outside the housing.

The proposed sensor according to the invention has several advantages. Due to the physical principle of the AMR sensor, only magnetic field angles relative to the AMR sensor of less than 180 degrees can be measured when the sensor is fully saturated. This is caused by the cos(2α) relationship between the sensor resistance and the angle α between the current and the magnetisation direction. The proposed inventive sensor configuration allows the measurement of angles over the complete 360 degrees while still using the AMR sensor technology and while still using a sensor in its saturated mode with all its advantages such as low noise and low sensitivity to external fields.

In the AMR angle sensors according to prior art, a strong permanent magnet is required for generating the magnetic field. This permanent magnet is attached to the rotating mechanism of which the angle has to be measured. The sensor has to be in the homogeneous part of the magnetic field which means that the magnet array normally is larger than the sensor package itself. This requires space. In the proposed sensor according to the invention, the permanent magnet is a part of the sensor package itself and is/can be smaller than the package. Thus no extra space around the mechanism of which the angle has to be measured is required and in principle the rotation angle of very small parts could be measured, e.g. diameters in the order of 1-2 mm or less. This will give more freedom in the design.

For a traditional angle sensor a strong magnetic field is required in order to completely saturate the magnetisation within the sensor. Since the magnet is at some distance from the sensor and has to be larger than the sensor, the size of the magnet has to be sufficient in order to generate that magnetic field. In the proposed sensor according to the invention also a strong magnetic field is present and all magnetic elements are in saturation. Since the magnet is much closer to the sensor, the size of the magnet can be smaller while the generated field strength is comparable with that of a traditional angle sensor. A smaller magnet will reduce the cost of the device. Moreover, the distance between the magnet and the sensor is fixed and thus the magnetic field strength which the sensor feels will be independent of the distance between the sensor and the mechanism of which the angle has to be measured.

In a traditional sensor according to prior art, the magnetic field moves together with the mechanism of which the angle has to be measured. This leads to a changing magnetic field in the surroundings of the mechanism. Especially when the mechanism rotates with a certain frequency, the changing magnetic fields can generate spurious induction voltages in nearby electronics. In the proposed sensor according to the invention, the generated magnetic field is static. Therefore, the environment feels a constant magnetic field and no eddy currents are generated.

Since the permanent magnet in the proposed sensor according to the invention may be smaller than the permanent magnet required in the traditional angle sensor, the stray field which is generated by the magnet and which might influence the surroundings, may be smaller.

In a traditional angle sensor according to prior art, the magnetisation is rotated by the applied magnetic field. A rotation of the field over 180 degrees also rotates the magnetisation over 180 degrees. During this rotation of the magnetisation, magnetic domain walls might change position although it should be mentioned that the applied field is strong. In the proposed sensor according to the invention, the magnetisation direction itself only rotates over a very small angle, leaving domain walls intact. This could lead to a lower noise in the output signal.

In a traditional AMR angle sensor according to prior art, the conversion from angle to output signal uses the physical relationship R=R₀+ΔR₀*cos²α between the resistance of the AMR element and the angle α between the magnetisation and the field direction. In the proposed sensor the conversion is a geometrical one between the rotation angle and the tilt angle of the bottom part of the rod. The tilt is finally converted to an output signal.

### BRIEF DESCRIPTION OF THE DRAWINGS

The above and other features and advantages of the invention will be apparent from the following description of an exemplary embodiment of the invention with reference to the accompanying drawings, in which:

FIG. 1 shows a schematic view of four inventive sensor arrangements;

FIG. 1a shows a schematic view of an inventive sensor;

FIG. 1b shows a schematic view of an inventive sensor;

FIG. 1c shows a schematic view of an inventive sensor;

FIG. 1d shows a schematic view of an inventive sensor;

FIG. 2 shows a schematic view of an inventive sensor;

FIG. 3 shows a schematic view of an inventive sensor;

FIG. 4 shows a schematic view of an inventive sensor;

### DETAILED DESCRIPTION OF THE DRAWINGS

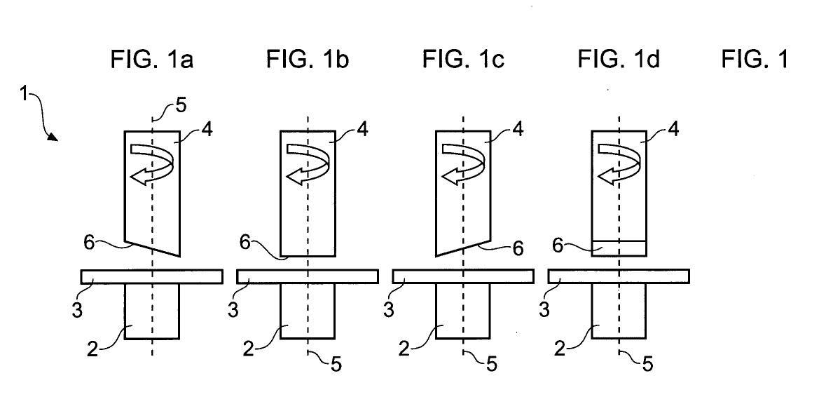

FIG. 1 shows a schematic view of four inventive sensor arrangements 1. FIG. 1a shows a permanent magnet 2 below a plane 3 which contains the sensor, referred to as sensor plate 3. Above the sensor plate 3 a cylindrical rod 4 is arranged. The rod 4 is rotatably or twistably arranged, where a mechanical connection from a driving element to the rod 4 may be provided eg. outside a housing. The cylindrical rod 4 has its length axis of rotation 5 perpendicular to the sensor surface. The bottom part 6 of the cylindrical rod 4 which is closest to the sensor surface of the sensor plate 3 is made of a magnetically conductive material. When the surface of the bottom part is perfectly parallel to the sensor surface, a rotation of the rod around its length axis will not change the orientation of the bottom surface relative to the sensor 3. However, when the bottom part 6 of the rod 4 is slightly tilted with respect to the rotation axis of the rod, a rotation of the rod 4 around this rotation axis will change the orientation of the tilted surface relative to the sensor 3, resulting in a certain tilt angle in X- and Y-direction and an accompanying signal in a X- and Y-Wheatstone-bridge of the sensor.

FIG. 1a shows a view of the sensor when the lower surface of the bottom part of the rod is tilted in one direction. FIG. 1b shows the sensor 1 where the rod is turned by 90°. The visible edge of the lower part of the rod 4 is parallel to the plane of the sensor 3. FIG. 1c shows the sensor 1 where the rod is turned by 180° and FIG. 1d shows the sensor 1 where the rod is turned by 270°.

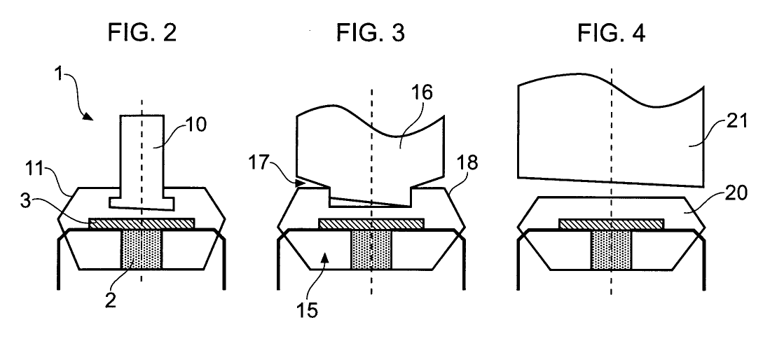

FIG. 2 shows an other embodiment of the inventive sensor 1 where the sensor 1 may contain an integrated rod 10 which can be rotated. In this embodiment the rod has a lower end integrated in the housing 11 of the sensor. This has the advantage that the rod 10 is always centered with respect to the sensor die and has a close distance to the sensor 3 which increases the signal intensity. The mechanism of which the angle has to be measured has to be attached to the packaged sensor outside the housing 11 of the sensor. The stand-alone package could also be used e.g. as a small contactless potentiometer.

According to an other embodiment of the invention, the packaged sensor 15 and the rod 16 can be isolated from each other. A recess 17 in the package or housing 18 could allow for a correct centering of the rod 16 and the rod or at least a part of the rod is arranged in the recess where a corner of the rod acts as a centering and/or as a bearing.

According to an other embodiment of the invention, the packaged sensor 20 and the rod 21 can be completely isolated from each other. The top of the package of the sensor 20 is flat. The rod 21 preferably is much larger than the package of the sensor 20 which gives more freedom in the design of the mechanism from which the angle has to be determines. As long as the diameter of the tilted surface is larger than the size of the sensor 20, alignment of the rod 21 with respect to the sensor is not critical.

1. Sensor arrangement comprising:
a magnet
a magnetic field sensor and
a twistable or rotatable rod
characterized in that the magnet is arranged on one side of the magnetic field sensor and the twistable or rotatable rod is arranged on the other side of the magnetic field sensor, wherein the rod comprises a lower surface of a magnetically conductive material generating a tilt angle between the surface and the plane of the magnetic field sensor.

2. Sensor arrangement according to claim 1, wherein the sensor arrangement comprises a housing, wherein the lower surface of the rod is arranged within the housing.

3. Sensor arrangement according to claim 1, wherein the housing comprises a recess and at least a part of the rod is arranged in the recess of the housing.

4. Sensor arrangement according to claim 3, wherein the recess is used to center the rod.

5. Sensor arrangement according to claim 3, wherein the recess is used as a bearing between housing and the rod.

6. Sensor arrangement according to claim 1, wherein the sensor arrangement comprises a housing, wherein the lower surface of the rod is arranged outside the housing.
